(19) United States
(12) Patent Application Publication
(10) Pub. No.: US 2009/0130832 A1
(43) Pub. Date: May 21, 2009

(54) SILICON SURFACE STRUCTURING METHOD

(75) Inventor: Detlef SONTAG, Freiberg (DE)

Correspondence Address: BROWDY AND NEIMARK, P.L.L.C.;624 NINTH STREET, NW, SUITE 300, WASHINGTON, DC, 20001-5303, US

(73) Assignee: Deutsche Cell GmbH, Freiberg/Sachsen (DE)

(21) Appl. No.: 12/272,689

(22) Filed: Nov. 17, 2008

(30) Foreign Application Priority Data
Nov. 15, 2007 (DE) 10 2007 054 485.7

(51) Int. Cl. H01L 21/22; B05D 3/02; B05D 5/00

(52) U.S. Cl. 438/542; 118/67; 257/E21.135

(57) ABSTRACT

A method for the structuring of multicrystalline silicon substrate surfaces and emitter diffusion into said surfaces comprises the following steps: providing a texturing solution which comprises at least a portion of phosphoric acid, providing a semiconductor substrate with a surface to be structured, coating the surface to be structured with the texturing solution, heating the texturing solution to a heating temperature T_{T}, and heating the texturing solution to a diffusion temperature T_{D}, wherein T_{D}>T_{T}.

### BACKGROUND OF THE INVENTION

1. Field of the Invention

The invention relates to a method for the structuring of multicrystalline silicon substrate surfaces and emitter diffusion into said surfaces as well as a device for the implementation of this method.

2. Background Art

According to prior art, texturing of silicon wafers and diffusing phosphorus into the silicon surface for forming a highly-doped emitter are two completely independent process steps during the production of a solar cell. Structuring of the surface usually takes place by means of an acid mixture which contains in particular hydrofluoric acid or nitric acid. In this process, the nitric mixture usually needs to be cooled to below 10° C. Emitter diffusion on the other hand takes place in a high-temperature gas phase process or in a continuous furnace. Consequently, separate installations are needed for silicon wafer texturing on the one hand and emitter diffusion on the other, which require twice the amount of space, lead to higher costs and increase the probability of downtimes and production losses.

### SUMMARY OF THE INVENTION

It is therefore the object of the invention to provide a method and a device which facilitate the surface texturing of a silicon substrate and the subsequent emitter diffusion into said surface.

This object is achieved by a method for the structuring of multicrystalline silicon substrate surfaces and emitter diffusion into said surfaces, the method comprising the following steps:
providing a texturing solution which comprises at least a portion of phosphoric acid;
providing a semiconductor substrate with a surface to be structured;
coating the surface to be structured with the texturing solution;
heating the texturing solution to a heating temperature T_{T};
heating the texturing solution to a diffusion temperature T_{D}, wherein T_{D}>T_{T}.

This object is further achieved by a device for the structuring of multicrystalline silicon substrate surfaces and emitter diffusion into said surface, the device comprising
a. a coating unit for coating a surface of a semiconductor substrate to be structured with a texturing solution;
b. at least one controllable heating device for heating the texturing solution to a texturing temperature T_{T} and a diffusion temperature T_{D}, wherein T_{D}>T_{T}.

The gist of the invention is to use a texturing solution for texturing a semiconductor substrate which has a texturing effect at high temperatures. As a result, the texturing process and the emitter diffusion can be combined particularly easily in an integrated process.

Further features and details of the invention will become apparent from the description of an embodiment by means of the drawing.

### BRIEF DESCRIPTION OF THE DRAWING

FIG. 1 is a schematic illustration of an embodiment of the invention.

### DESCRIPTION OF THE PREFERRED EMBODIMENT

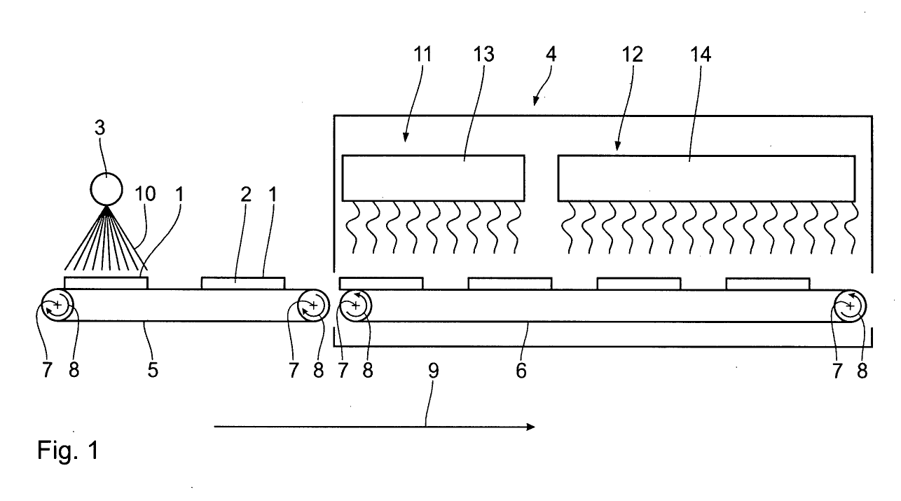

The following is a description, with reference to FIG. 1, of an embodiment of the invention. A device for structuring a surface 1 of a semiconductor substrate 2 comprises a coating unit 3 as well as at least one controllable heating device. It is in particular intended that the heating device is designed as a continuous furnace 4. The device further comprises a first conveyor belt 5, which is arranged in the region of the coating unit 3, and a second conveyor belt 6, which is at least partially arranged in the region of the continuous furnace 4. The conveyor belts 5 and 6 are in each case supported on conveyor rollers 7 for rotary drive. The conveyor rollers 7 are mounted for rotary drive in a direction of rotation 8. The conveyor belts 5 and 6 are an example of a conveyor unit by means of which the semiconductor substrate 2 is conveyable through the device in a conveyance direction 9. The surface 1 to be structured is coatable with a texturing solution 10 by means of the coating unit 3.

The texturing solution 10 comprises at least a portion of phosphoric acid. It consists in particular of pure phosphoric acid. The concentration of the phosphoric acid in the texturing solution amounts to at least 70%, in particular at least 80%, in particular at least 85%.

Seen in the conveyance direction 9, the continuous furnace 4 is arranged downstream of the coating unit 3. The continuous furnace 4 comprises at least one first zone 11 and a second zone 12 arranged downstream thereof when seen in the conveyance direction 9. A first heating device 13 is arranged in the region of the first zone 11. In the region of the second zone 12 is arranged a second heating device 14. In the region of the first zone 11, the texturing solution 10 on the surface 1 of the semiconductor substrate 2 is heatable to a texturing temperature T_{T} by means of the first heating device 13. The texturing temperature T_{T} amounts to at least 250° C., in particular at least 300° C., in particular at least 350° C. In the region of the second zone 12, the texturing solution 10 on the surface 1 of the semiconductor substrate 2 is heatable to a diffusion temperature T_{D} by means of the second heating device 14. The diffusion temperature T_{D} amounts to at least 500° C., in particular at least 600° C., in particular at least 750° C. The second heating device 14, which is arranged downstream of the first heating device 13 when seen in the conveyance direction 9, enables a particularly efficient combination of the structuring process and the diffusion process to be achieved. Likewise, it is also conceivable to arrange the first heating device 13 and the second heating device 14 in such a way that they at least partially overlap with each other when seen in the conveyance direction 9. The heating devices 13 and 14 are operable in particular in a sequential or cumulative manner.

The following is a description of the functioning of the device according to the invention. The texturing solution 10 is at first applied to at least one surface 1 of the semiconductor substrate 2 by means of the coating unit 3. The texturing solution 10 is in particular applied to the surface 1 of the semiconductor substrate 2 by means of a spray-on technique. A spin-coating process (spin-on technique) is possible as well. A metering device not shown in the FIGURE allows the amounts of texturing solution 10 applied to the surface 1 of the semiconductor substrate 2 to be precisely metered. The surface 1 of the semiconductor substrate 2 is thus coated with a predetermined amount of texturing solution 10. The surface 1 of the semiconductor substrate 2 is in particular evenly coated, in other words after the coating process, the amount of texturing solution 10 is constant across the entire surface 1 of the semiconductor substrate 2.

Upstream of the first conveyor belt 5, the semiconductor substrate 2, which is coated with the texturing solution 10, is conveyed to the heating device in the conveyance direction 9. In the heating device configured as a continuous furnace 4, the coated semiconductor substrate 2 initially passes through the first zone 11 with the first heating device 13. In the region of the first zone 11, the texturing solution 10 on the surface 1 of the semiconductor substrate 2 is at first heated to the texturing temperature T_{T} by means of the first heating device 13. When orthophosphoric acid is heated to at least 200° C., this results in a loss of water, thus causing pyrophosphoric acid to form. Pyrophosphoric acid is a much stronger acid than orthophosphoric acid. When further heated to a temperature of at least 300° C., even more water is separated from the pyrophosphoric acid, which initially causes higher polyphosphoric acids to form which then convert into metaphosphoric acid. This condensation process causes the acid strength to increase. It has been discovered that a texturing temperature T_{T} above a minimum temperature triggers a structuring process on the surface 1 of the semiconductor substrate 2 which causes small gas bubbles to form. It is crucial for the structuring process that the texturing solution comprises at least a portion of pyrophosphoric acid and/or metaphosphoric acid.

By means of the second conveyor belt 6, the semiconductor substrate 2 is advanced further through the continuous furnace 4 in the conveyance direction 9. Having passed through the first zone 11, the semiconductor substrate 2 reaches the region of the second zone 12 with the second heating device 14. The second heating device 14 is used to heat the texturing solution 10 on the surface 1 of the semiconductor substrate 2 to the diffusion temperature T_{D}. When the texturing solution 10 is heated to the diffusion temperature T_{D}, this causes phosphorus to diffuse into the surface 1 of the semiconductor substrate 2 in such a way that a highly doped emitter is formed in the surface 1 of the semiconductor substrate 2.

Having passed through the continuous furnace 4, the phosphorus glass, which has been generated during the diffusion process, is removed in the usual way, as it is known from a conventional diffusion process.

What is claimed is:

1. A method for the structuring of multicrystalline silicon substrate surfaces and emitter diffusion into said surfaces, the method comprising the following steps:
providing a texturing solution (10) which comprises at least a portion of phosphoric acid;
providing a semiconductor substrate (2) with a surface (1) to be structured;
coating the surface (1) to be structured with the texturing solution (10);
heating the texturing solution (10) to a heating temperature T_{T};
heating the texturing solution (10) to a diffusion temperature T_{D}, wherein T_{D}>T_{T}.

2. A method according to claim 1, wherein the texturing temperature T_{T} amounts to at least 250° C.

3. A method according to claim 1, wherein the texturing temperature T_{T} amounts to at least 300° C.

4. A method according to claim 1, wherein the texturing temperature T_{T} amounts to at least 350° C.

5. A method according to claim 1, wherein the diffusion temperature T_{D} amounts to at least 500° C.

6. A method according to claim 1, wherein the diffusion temperature T_{D} amounts to at least 600° C.

7. A method according to claim 1, wherein the diffusion temperature T_{D} amounts to at least 750° C.

8. A method according to claim 1, wherein at the texturing temperature T_{T}, the texturing solution (10) comprises at least a portion of at least one of pyrophosphoric acid and metaphosphoric acid.

9. A method according to claim 1, wherein the texturing solution (10) consists of pure phosphoric acid.

10. A method according to claim 1, wherein the heating of the texturizing solution to the texturizing temperature T_{T} and the heating of the texturizing solution to the diffusion temperature T_{D} takes place in a single continuous furnace (4).

11. A device for the structuring of multicrystalline silicon substrate surfaces and emitter diffusion into said surface, the device comprising
a. a coating unit (3) for coating a surface (11) of a semiconductor substrate (2) to be structured with a texturing solution (10);
b. at least one controllable heating device for heating the texturing solution (10) to a texturing temperature T_{T} and a diffusion temperature T_{D}, wherein T_{D}>T_{T}.

12. A device according to claim 11, wherein the at least one heating device is a continuous furnace (4).

13. A device according to claim 12, wherein the continuous furnace (4) comprises a first zone (11) with a first heating device (13) and a second zone (12) with a second heating device (14).
